(19) United States
(12) Patent Application Publication
(10) Pub. No.: US 2015/0270003 A1
(43) Pub. Date: Sep. 24, 2015

(54) NON-VOLATILE MEMORY AND METHOD FOR PROGRAMMING THE SAME

(71) Applicant: SK hynix Inc., Gyeonggi-do (KR)

(72) Inventors: Byoung-Kwan JEONG, Gyeonggi-do (KR); Seong-Je PARK, Gyeonggi-do (KR)

(21) Appl. No.: 14/466,680

(22) Filed: Aug. 22, 2014

(30) Foreign Application Priority Data
Mar. 21, 2014 (KR) 10-2014-0033271

(51) Int. Cl. G11C 16/10; G11C 16/34

(52) U.S. Cl. CPC G11C 16/10; G11C 16/3459

(57) ABSTRACT

A method for programming a non-volatile memory includes applying a first program pulse to a program cell one or more times until a threshold voltage of the program cell reaches a preliminary target voltage, which is lower than a target voltage, while supplying a first voltage to a bit line corresponding to the program cell, and applying a second program pulse to the program cell a predetermined number of times while supplying a second voltage, which is higher to than the first voltage, to the bit line after the threshold voltage of the program cell reaches the preliminary target voltage.

### CROSS-REFERENCE TO RELATED APPLICATIONS

The present application claims priority of Korean Patent Application No. 10-2014-0033271, filed on Mar. 21, 2014, which is incorporated herein by reference in its entirety.

### BACKGROUND

1. Field

Exemplary embodiments of the present invention relate to a non-volatile memory and a method for programming the same.

2. Description of the Related Art

There are various methods for programming non-volatile memory. To prevent threshold voltages of programmed memory cells from having a wide distribution, an Incremental Step Pulse Program (ISPP) program scheme is generally used. The program operation of the ISPP scheme begins with a low level program pulse that is then gradually raised. To be specific, after raising threshold voltages of selected memory cells by applying the program pulse to a selected word line, a verification operation is performed to check whether the threshold voltages of the selected memory cells reach a target level. A process of raising the program pulse and performing a program operation with the raised program pulse is repeated until the threshold voltages of the selected memory cells reach the target level by performing the verification operation.

The methods for programming a non-volatile memory with an improved ISPP scheme are being studied to narrow the distribution width of the threshold voltages of programmed memory cells. Among the methods is a programming method of the ISPP scheme using a double verification operation, which is also referred to as a double program operation.

The double verification operation may narrow the distribution width of the threshold voltages of programmed memory cells by degrading a threshold voltage increase rate of memory cells which are close to a target level. As the threshold voltages of the memory cells which are close to the target level increase rapidly, the distribution width of the threshold voltages of the programmed memory cells may broaden. The double verification operation may narrow the distribution width of the threshold voltages of the programmed memory cells by gradually raising the threshold voltages of the memory cells which are close to the target level. To this end, the verification operation is performed using the target level and a preliminary target level which is lower than the target level. To be specific, two verification operations, a first verification operation using the preliminary target level and a second verification operation using the target level, are performed after the program pulse is applied. As a result, it verified (1) whether threshold voltages of corresponding cells are lower than a preliminary target level, or (2) whether threshold voltages of corresponding cells are between a preliminary target level and a target level, or (3) whether threshold voltages of corresponding cells reach a target level. Also, the threshold voltages of the corresponding cells (1) are programmed to increase by a relatively large amount, (2) are programmed to increase by a relatively small amount, or (3) do not fluctuate, based on a method of controlling a level of a bit line.

However, the program method as described above may consume more time to perform the entire program operation since two verification operations are to be performed whenever the program pulse is applied.

### SUMMARY

Exemplary embodiments of the present invention are directed to a non-volatile memory that may reduce program operation time while narrowing the distribution width of threshold voltages, and a method for programming the non-volatile memory.

In accordance with an embodiment of the present invention, a method for programming a non-volatile memory includes applying a first program pulse to a program cell one or more times until a threshold voltage of the program cell reaches a preliminary target voltage, which is lower than a target voltage, while supplying a first voltage to a bit line corresponding to the program cell, and applying a second program pulse to the program cell a predetermined number of times while supplying a second voltage, which is higher than the first voltage, to the bit line after the threshold voltage of the program cell reaches the preliminary target voltage.

The method for programming the non-volatile memory may further include supplying an inhibit voltage to the bit line after the applying of the second program pulse to the program cell the predetermined number of times.

In accordance with another embodiment of the present invention, a method for programming a non-volatile memory includes supplying a first voltage to a bit line corresponding to a program cell, applying a first program pulse to a word line corresponding to the program cell while the first voltage is supplied to the bit line, verifying the program cell based on a voltage level which is lower than a target threshold voltage level, supplying a second voltage which is higher than the first voltage to the bit line when the program cell passes in the verifying of the program cell and applying a second program pulse to the word line a predetermined number of times while the second voltage is supplied to the bit line.

The method for programming the non-volatile memory may further include supplying an inhibit voltage to the bit line after the applying of the second program pulse to a word line the predetermined number of times.

In accordance with an embodiment of the present invention, a non-volatile memory includes a cell array including a plurality of memory cells, and one or more circuits suitable for performing a program operation of the cell array, wherein during a program operation of a first cell among the memory cells, the circuit applies a first program pulse to the first cell one or more times until a threshold voltage of the first cell reaches a preliminary target voltage, which is lower than a target voltage, while supplying a first voltage to a bit line corresponding to the first cell, and applies a second program pulse to the first cell a predetermined number of times while supplying a second voltage, which is higher than the first voltage, to the bit line after the threshold voltage of the first cell reaches the preliminary target voltage.

The circuit may supply an inhibit voltage to the bit line after the second program pulse is applied to the first cell the predetermined number of times.

In accordance with an embodiment of the present invention, a method for programming a non-volatile memory includes applying a program pulse to a word line corresponding to a program cell while supplying a first voltage to a bit line corresponding to a program cell, verifying whether a threshold voltage of the program cell reaches a target voltage, increasing a level of the program pulse and repeating the applying of the program pulse when the threshold voltage of the program cell is lower than the target voltage in the verifying, and applying the program pulse to the word line a predetermined number of times while supplying a second voltage higher than the first voltage to the bit line and increasing the level of the program pulse each time when the threshold voltage of the program cell is equal to or higher than the target voltage in the verifying.

### BRIEF DESCRIPTION OF THE DRAWINGS

FIG. 1 is a block diagram illustrating an internal structure of a non-volatile memory in accordance with an embodiment of the present invention.

FIG. 2 is a flowchart illustrating a method for programming a non-volatile memory in accordance with an embodiment of the present invention.

FIGS. 3A to 3C show variation of the threshold voltage of program cells during a program operation.

### DETAILED DESCRIPTION

Exemplary embodiments of the present invention are described below in more detail with reference to the accompanying drawings. These embodiments are provided so that this disclosure will be thorough complete, and fully convey the scope of the present invention to those skilled in the art.

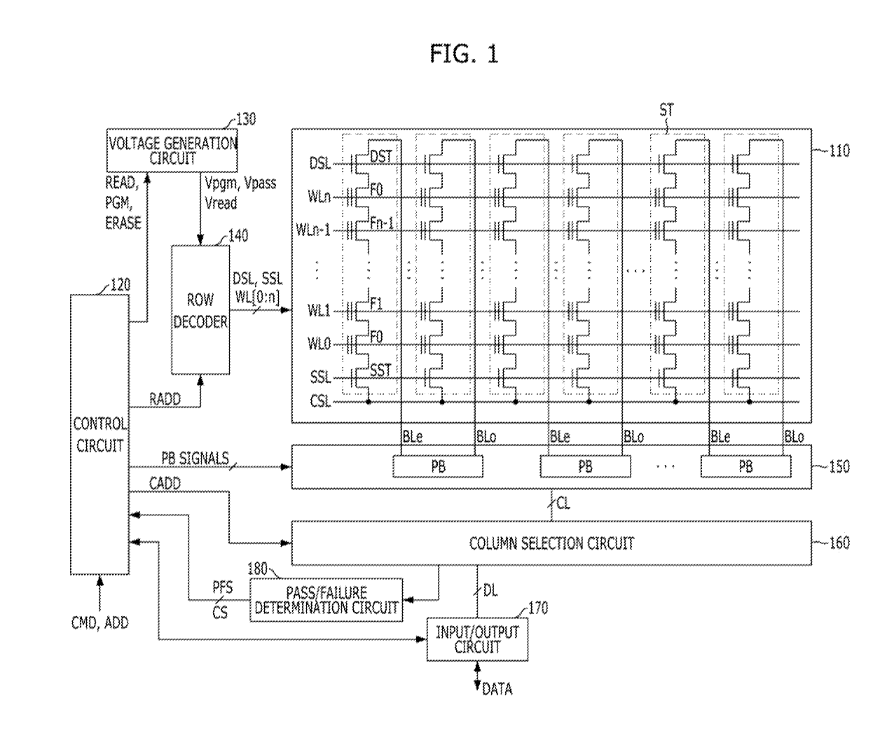

FIG. 1 is a block diagram illustrating an internal structure of a non-volatile memory in accordance with an embodiment of the present invention.

Referring to FIG. 1, a non-volatile memory device may include a cell array 110 and a control circuit 120 which controls circuits 130, 140, 150, 160, 170 and 180 performing program operations or read operations of memory cells included in the cell array 110. The circuits may include a voltage generation circuit 130, a row decoder 140, a page buffer group 150, a column selection circuit 160, an input/output circuit 170 and a pass/failure determination circuit 180.

The cell array 110 may include a plurality of memory cell blocks, and FIG. 1 illustrates one memory cell block among the memory cell blocks. Each of the memory cell blocks may include a plurality of strings ST. A portion of the strings ST may be designated as normal strings, and another portion of the strings ST may be designated as flag strings. The strings ST may have the same structure, and each of the strings ST may be formed of a source selection transistor SST coupled with a common source line CSL, a plurality of cells F0 to Fn, and a drain selection transistor DST coupled with a bit line BL. Cells included in the flag string are referred to as flag cells, and cells included in the normal string are referred to as normal cells, i.e., memory cells. The structures of the flag cells may be the same as the structures of the memory cells. A gate of the source selection transistor SST may be coupled with a source selection line SSL, and gates of the memory cells F0 to Fn may be coupled with word lines WL0 to WLn, and a gate of the drain selection transistor DST may be coupled with a drain selection line DSL. The strings ST may be coupled with bit lines BLe and BLo corresponding to the strings ST, respectively, and they may be coupled with the common source line CSL in common.

The control circuit 120 may output a program operation signal PGM, a read operation signal READ or an erase operation signal ERASE in response to a command signal CMD, and output page buffer signals PB SIGNALS for controlling page buffers included in the page buffer group 150 based on kinds of operations to be performed to internally. Also, the control circuit 120 may output a row address signal RADD and a column address signal CADD in response to an address signal ADD internally. The control circuit 120 may check whether threshold voltages of selected memory cells is raised to a target voltage based on a check signal CS, which is outputted from the pass/failure determination circuit 180, during a program verification operation, and determine whether to perform the program operation again or terminate the program operation based on the check result.

Voltage supply circuits 130 and 140 may supply voltages which are required for a program operation, an erase operation or a read operation of the memory cells to the drain selection line DSL, the word lines WL0 to WLn and the source selection line SSL of the selected memory cell block based on the signals READ, PGM, ERASE and RADD of the control circuit 120. The voltage supply circuits may include the voltage generation circuit 130 and the row decoder 140.

The voltage generation circuit 130 may output operation voltages for programming, reading or erasing the memory cells to global lines in response to the operation signals PGM, READ and ERASE which are internal command signals of the control circuit 120. Also, the voltage generation circuit 130 may output the operation voltages, e.g., Vpgm, Vpass and Vread, for programming the memory cells to the global lines when the memory cells are programmed.

The row decoder 140 may transfer the operation voltages which are generated in the voltage generation circuit 130 to local lines DSL, WL[0:n] and SSL of the selected memory cell block in response to the row address signal RADD of the control circuit 120.

The page buffer group 150 may include page buffers PB which are coupled with the bit lines BLe and BLo. The page buffer group 150 may supply voltages which are required for storing data in the memory cells F0 to Fn to the bit lines BLe and BLo in response to the page buffer signals PB SIGNALS outputted from the control circuit 120. To be specific, the page buffer group 150 may precharge the bit lines BLe and BLo, or latch data corresponding to the threshold voltage levels of the memory cells F0 to Fn by detecting voltage changes of the bit lines BLe and BLo during the program operation, the erase operation or the read operation of the memory cells F0 to Fn. In other words, the page buffer group 150 may supply a program allowable voltage, e.g., 0V or 0+αV, or a program inhibit voltage, e.g., Vcc, to the bit lines BLe and BLo based on the data inputted to a latch during the program operation, and detect data stored in the memory cells F0 to Fn by controlling the voltages of the bit lines BLe and BLo based on the data stored in the memory cells F0 to Fn during the read operation.

The column selection circuit 160 may select the page buffers PB included in the page buffer group 150 in response to the column address signal CADD outputted from the control circuit 120. A latched data of the page buffer PB selected by the column selection circuit 160 may be outputted. Also, the column selection circuit 160 may receive the data outputted from the page buffer group 150 through a column line CL and transfer the data to the pass/failure determination circuit 180.

The input/output circuit 170 may transfer a data DATA inputted from an exterior to the column selection circuit 160 under the control of the control circuit 120 in order to input the data DATA to the page buffers PB of the page buffer group 150 during the program operation. When the column selection circuit 160 sequentially transfers the transferred data to the page buffers PB of the page buffer group 150, the page buffers PB may store the inputted data in an internal latch. Also, the input/output circuit 170 may output the data DATA which is transferred from the page buffers PB of the page buffer group 150 through the column selection circuit 160 to an exterior during the read operation.

The pass/failure determination circuit 180 may determine whether the program operation is completed and output the determination result as a check signal PFC. Also, the pass/failure determination circuit 180 may count the number of failure cells while failure occurs and output the counting result as a counting signal CS.

The control circuit 120 may control the voltage generation circuit 130 to control the level of the program voltage supplied to the selected word line during the program operation of the memory cells and to selectively apply the verification voltages to the selected word line during the program verification operation. The control circuit 120 may control the voltage generation circuit 130 based on the check signal CS of the pass/failure determination circuit 180.

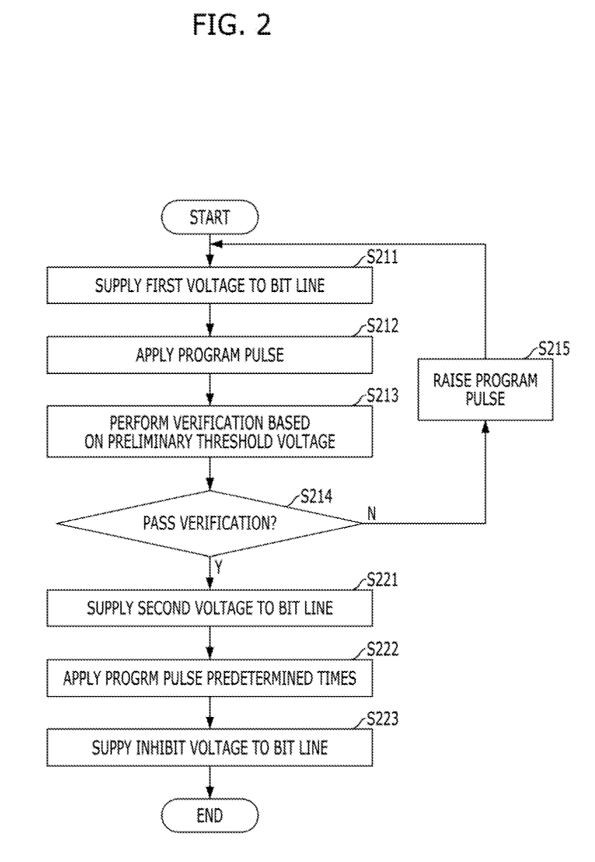

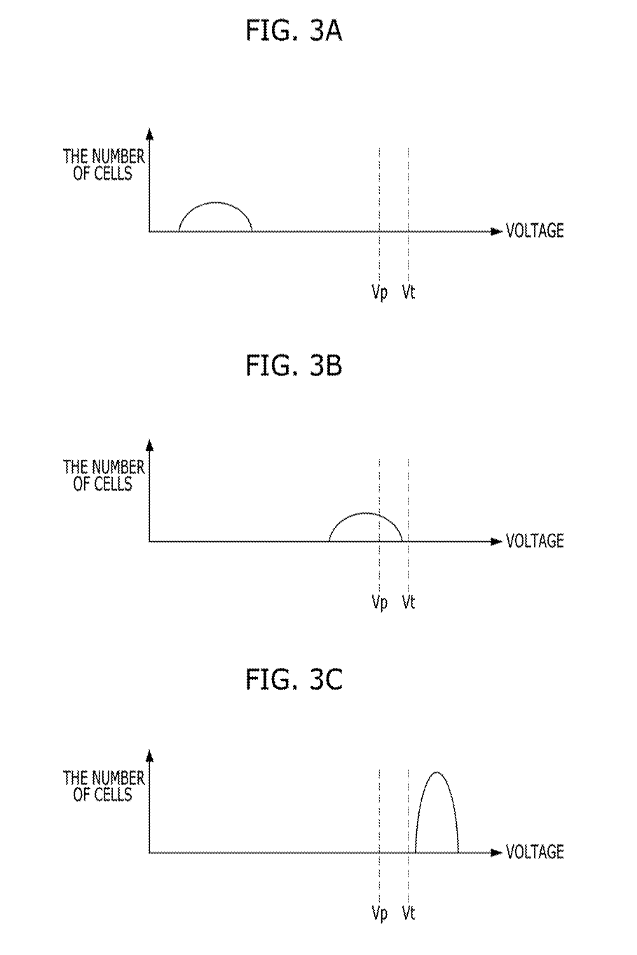

FIG. 2 is a flowchart illustrating a method for programming the non-volatile memory in accordance with an embodiment of the present invention. FIGS. 3A to 3C show variation of the threshold voltage of the program cells during the program operation.

Referring to FIG. 2 and FIGS. 3A to 3C, the method for programming the non-volatile memory is described in detail.

(1) A step of programming the program cells to the preliminary target voltage Vp.

As shown in FIG. 3A, the program cells of an erase state are programmed to the preliminary target voltage Vp. The program cells indicate memory cells on which the program operation is performed among the memory cells. In other words, the program cells are the memory cells selected based on an address to be programmed with program data during the program operation.

A first voltage, e.g., 0V, which is a program allowable voltage, may be supplied to a bit line corresponding to the program cell in step S211. A program inhibit voltage, e.g., a power source voltage, may be supplied to a bit line corresponding to an erase cell.

Subsequently, a program pulse of a high voltage may be applied to a word line corresponding to the program cell in step S212. The level of the program pulse may increase each time. For example, when the voltage level of the program pulse is approximately 14V while the program pulse is applied at first, the voltage level of the program pulse may increase by approximately 1V whenever the program pulse is applied.

After the program pulse is applied, the program cell may be verified on the basis of the preliminary target voltage Vp in step S213. This may indicate whether a threshold voltage of the program cell is higher or lower than the preliminary target voltage Vp. The level of the preliminary target voltage Vp may be lower than the target level Vt that the threshold voltage of the program cell will finally have. When it turns out as the verification result of the program cell threshold voltage is higher than the preliminary target voltage Vp (in other words, when the program cell is distributed on the right side of the preliminary target voltage Vp in FIG. 3B), it is determined that the program cell passes the verification (‘YES’) in step S214, and the logic flow goes to the next step. However, when the verification result of the program cell threshold voltage is lower than the preliminary target voltage Vp (in other words, when the program cell is distributed on the left side of the preliminary target voltage Vp in FIG. 3B), it is determined that the verification fails (‘NO’) in step S214, and the level of the program pulse is raised in step S215, and the processes of steps S211 to S214 are carried out again.

As the processes of the steps S211 to S214 are carried out, the threshold voltage of the program cell becomes higher than the preliminary target voltage Vp.

(2) A step of blind-programming the program cells which reach the preliminary target voltage Vp.

The program cells which have reached the preliminary target voltage Vp are blind-programmed. The program pulse is applied the predetermined number of times to the program cells which have reached the preliminary target voltage Vp regardless of the verification result. For this reason, this program operation is referred to as a blind program.

A second voltage, e.g., 0+αV, which is higher than the first voltage, e.g., 0V, may be supplied to a bit line corresponding to the program cell which has reached the preliminary target voltage Vp in step S221. The second voltage is supplied to the bit line in order to make the threshold voltage of the program cell change within a small fluctuation width although the program pulse is supplied to the program cell.

In a state where the second voltage is supplied to the bit line, the program pulse may be applied the predetermined number of times, e.g., once or three times, to a word line corresponding to the program cell in step S222. A voltage level of the applied program pulse may be higher than a voltage level of the program pulse which is applied in the last step of programming the memory cell to the preliminary target voltage Vp. When the predetermined number of times is more than twice, the voltage level of the program pulse may increase whenever the program pulse is applied. As the program pulse is applied in the step S222, the threshold voltage of the program cell may change to have a small width, and then have a threshold voltage distribution as shown in FIG. 3C.

After the program pulse is applied the predetermined number of times, an inhibit voltage, e.g., a power source voltage, may be supplied to a bit line of the program cell in step S223. As a result, the threshold voltage of the program cell may be prevented from changing.

In the steps S221 to S223, the program pulse is applied the predetermined number of times to the program cells of which the threshold voltages reach the preliminary target voltage Vp, regardless of the verification operation, in a state where the bit line is set so that the threshold voltages may change just a little bit. Therefore, although the threshold voltage of the program cell changes a little bit based on the performance of the steps S221 to S223, the threshold voltage of the program cell may have a threshold voltage distribution as shown in FIG. 3C

In accordance with the embodiments of the present invention, a threshold voltage distribution width of program cells may be reduced while program operation time is prevented from increasing as a verification operation is performed on the basis of one voltage level.

In accordance with the embodiments of the present invention, it is possible to narrow the distribution width of threshold voltages of program cells and reduce program operation time in a non-volatile memory.

While the present invention has been described with respect to the specific embodiments, it is noted that the embodiments of the present invention are not restrictive but descriptive. Further, it is noted that the present invention may be achieved in various ways through substitution, change, and modification, by those skilled in the art without departing from the scope of the present invention as defined by the following claims.

What is claimed is:

1. A method for programming a non-volatile memory comprising:
applying a first program pulse to a program cell one or more times until a threshold voltage of the program cell reaches a preliminary target voltage, which is lower than a target voltage, while supplying a first voltage to a bit line corresponding to the program cell; and
applying a second program pulse to the program cell a predetermined number of times while supplying a second voltage, which is higher than the first voltage, to the bit line after the threshold voltage of the program cell reaches the preliminary target voltage.

2. The method of claim 1, further comprising:
supplying an inhibit voltage to the bit line after the applying of the second program pulse to the program cell the predetermined number of times.

3. The method of claim 1, wherein in the applying of the first program pulse to the program cell one or more times and in the applying of the second program pulse to the program cell the predetermined number of times,
a voltage level of the first program pulse and a voltage level of the second program pulse increase every time.

4. The method of claim 3, wherein an initial voltage level of the second program pulse is higher than a last voltage level of the first program pulse.

5. A method for programming a non-volatile memory, comprising:
supplying a first voltage to a bit line corresponding to a program cell;
applying a first program pulse to a word line corresponding to the program cell while the first voltage is supplied to the bit line;
verifying the program cell based on a voltage level which is lower than a target threshold voltage level;
supplying a second voltage which is higher than the first voltage to the bit line when the program cell passes in the verifying of the program cell; and
applying a second program pulse to the word line a predetermined number of times while the second voltage is supplied to the bit line.

6. The method of claim 5, further comprising:
supplying an inhibit voltage to the bit line after the applying of the second program pulse to word line the predetermined number of times.

7. The method of claim 5, further comprising:
repeating the applying of the first program pulse based on an ISPP scheme while the first voltage is supplied to the bit line, when the program cell fails in the verifying of the program cell.

8. The method of claim 5, wherein, in the applying of the second program pulse to word line the predetermined number of times while the second voltage is supplied to the bit line,
a voltage level of the second program pulse increases every time.

9. A non-volatile memory, comprising:
a cell, array including a plurality of memory cells; and
one or more circuits suitable for performing a program operation of the cell array,
wherein during a program operation of a first cell among the memory cells, the circuit applies a first program pulse to the first cell one or more times until a threshold voltage of the first cell reaches a preliminary target voltage, which is lower than a target voltage, while supplying a first voltage to a bit line corresponding to the first cell, and applies a second program pulse to the first cell a predetermined number of times while supplying a second voltage, which is higher than the first voltage, to the bit line after the threshold voltage of the first cell reaches the preliminary target voltage.

10. The non-volatile memory of claim 9, wherein the circuit supplies an inhibit voltage to the bit line after the second program pulse is applied to the first cell the predetermined number of times.
